(19) United States
(12) Patent Application Publication
(10) Pub. No.: US 2009/0071693 A1
(43) Pub. Date: Mar. 19, 2009

(54) NEGATIVE PHOTOSENSITIVE MATERIAL AND CIRCUIT BOARD

(75) Inventors: Jun TOKUHIRO, Ichihara-shi (JP); Hiroyuki Sekino, Ichihara-shi (JP); Mitsuaki Chida, Mobara-shi (JP); Kenji Suzuki, Ichihara-shi (JP)

Correspondence Address: BUCHANAN, INGERSOLL & ROONEY PC, POST OFFICE BOX 1404, ALEXANDRIA, VA, 22313-1404, US

(73) Assignee: MITSUI CHEMICALS, INC., Tokyo (JP)

(21) Appl. No.: 12/201,858

(22) Filed: Aug. 29, 2008

Related U.S. Application Data
(60) Provisional application No. 60/935,775, filed on Aug. 30, 2007.

(51) Int. Cl. H05K 1/00; G03F 7/004; G03F 7/09

(52) U.S. Cl. 174/250; 430/270.1; 430/275.1

(57) ABSTRACT

To provide a negative photosensitive material containing a quaternary ammonium salt in an amount of 5 to 30 weight parts based on 100 weight parts of a polyimide precursor having repeating units of the following general formula (I), wherein said quaternary ammonium salt is a photobase generator for generating a tertiary amine by irradiation with an active ray, and said tertiary amine contains one or more nitrogen atoms and oxygen atoms respectively in a molecule,

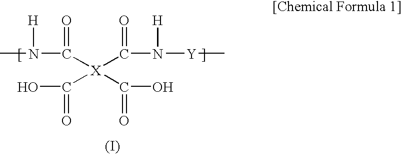

wherein, in the formula (I), X is a tetravalent aliphatic group or a tetravalent aromatic group; and Y is a divalent aliphatic group or a divalent aromatic group.

### REFERENCE TO RELATED PATENT

This application is entitled to the benefit of a provisional application Ser. No. 60/935,775 filed to the US Patent and Trademark Office as of Aug. 30, 2007.

### TECHNICAL FIELD

The present invention relates to a photosensitive material and a circuit board prepared by using the photosensitive material.

### BACKGROUND ART

For the purpose of achieving high-density mounting and high-speed signal processing, thin film multilayered boards have been paid attention to. In particular, circuit boards have been used in which a polyimide resin excellent in heat resistance is arranged as an insulation layer on a metal foil. As materials for the protection layer for interconnections formed on such a circuit board, polyimide resins have also been used. In connection with recent demand for greater packing density, high-precision processing is demanded also for polyimide used as an insulation layer and/or protection layer as in the case of metal foils to be processed into interconnections. Among these circuit boards, circuit boards for HDD suspensions are becoming denser and denser with increasing demand for smaller, lighter HDD suspensions.

For processing of polyimide, methods of mechanical punching, dry etching, wet etching and the like have been usually used, and for more precise processing, it is preferable that the polyimide itself be provided with photosensitivity for direct light exposure and development for pattern formation.

As a method for giving photosensitivity to polyimide, there has been well known that a photopolymerizable functional group is introduced by an ester bond or an ionic bond to a side chain of a polyamic acid that is a polyimide precursor, and also a photopolymerization initiator has been combined therewith (refer to Patent Documents 1 to 3 and the like). There are also proposed methods of imparting photosensitivity in which a polyamic acid and a photoacid generator are combined (refer to Patent Document 4, for example) or a polyamic acid and photobase generator are combined (refer to Patent Documents 5 to 7, for example). As the photobase generator, for example, a quaternary ammonium salt represented by the following general formula (a) has been proposed (refer to Patent Document 8),

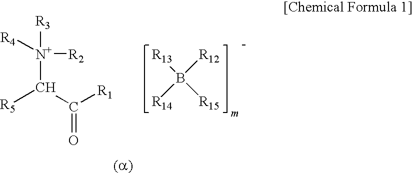

wherein R represents phenyl, naphthyl or the like; R₂ to R₄ each represent hydrogen, C1 to C18 alkyl, phenyl or the like; R₅ represents hydrogen, C1 to C18 alkyl or the like; and R₁₂ to R₁₄ each represent phenyl, other aromatic hydrogen or the like.

Furthermore, as the photobase generator, for example, a quaternary ammonium salt represented by the following general formula (β) has been proposed and a method for providing photosensitivity to polyimide has also been proposed by adding this photobase generator to polyamic acid ester that is a polyimide precursor (refer to Patent Document 9). In this way, a polyimide precursor solution with a photobase generator added thereto is exposed to light, and differences are given in solubility with respect to developing solution such as an aqueous alkali solution between exposed portions and unexposed portions, whereby a developing property is obtained.

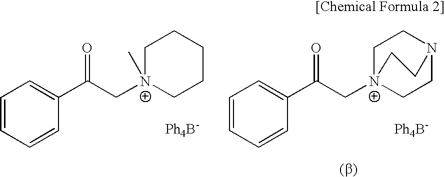

However, a polyimide layer to be an insulation layer or a protection layer is required to have a thickness of not less than several microns. Such a thick film has been required to have high photosensitivity, i.e., high developing property such that it can also be patterned. In particular, to use a polyimide resin as a photosensitive material for a circuit board, characteristics equivalent to those of a non-photosensitive polyimide material, for example, heat resistance, low linear thermal expansion coefficient and film strength, have been required. In particular, polyimide to be an insulation layer or a protection layer of a suspension board of a magnetic recording device has been required to have low linear thermal expansion coefficient for preventing a warpage behavior of the suspension board from varying due to temperature change.

Patent Document 1: Japanese Patent Application Laid-open No. 1985-228537

Patent Document 2: Japanese Patent Publication No. 1984-52822

Patent Document 3: Japanese Patent Application Laid-open No. 2006-98514

Patent Document 4: Japanese Patent Application Laid-open No. 2005-148111

Patent Document 5: Japanese Patent Application Laid-open No. 2007-86763

Patent Document 6: Japanese Patent Application Laid-open No. 1996-227154

Patent Document 7: Japanese Patent Application Laid-open No. 2006-189591

Patent Document 8: Japanese Patent Application Laid-open No. 2001-513765

Patent Document 9: Japanese Patent Application Laid-open No. 2003-084435

### DISCLOSURE OF THE INVENTION

An object of the present invention is to inexpensively provide a negative photosensitive material which has a linear thermal expansion coefficient equivalent to that of a metal foil to be a board, excellent photosensitivity and high developing property with an aqueous alkali solution, and a circuit board prepared using the negative photosensitive material.

In particular, a polyimide with a low linear thermal expansion coefficient generally has a highly rigid molecular structure. However, the peak of the wavelength of light to be absorbed by polyimide having a highly rigid molecular structure shifts to longer wavelengths. Accordingly, in a thick polyimide film, light hardly penetrates in the thickness direction so that imidization (photo-curing) becomes difficult in some cases. The object is to provide a developable negative photosensitive material including such a polyimide precursor.

In order to achieve the above objects, the present inventors have repeatedly conducted extensive studies and, as a result, have found that the above objects can be achieved by combining a quaternary ammonium salt for generating a tertiary amine of a specific structure by irradiation with an active ray with a polyimide precursor. Thus, the present invention has been completed.

[1] A negative photosensitive material containing a quaternary ammonium salt in an amount of 5 to 30 weight parts, based on 100 weight parts of a polyimide precursor having repeating units of the following general formula (I), wherein the quaternary ammonium salt is a photobase generator for generating a tertiary amine by irradiation with an active ray, and the tertiary amine contains one or more nitrogen atoms and oxygen atoms respectively in a molecule.

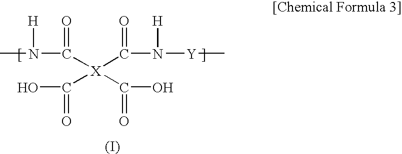

In the formula (I), X is a tetravalent aliphatic group or a tetravalent aromatic group; and Y is a divalent aliphatic group or a divalent aromatic group.

[2] The negative photosensitive material according to [1], wherein the tertiary amine is a tertiary aliphatic amine.

[3] The negative photosensitive material according to [1] or [2], wherein nitrogen atoms and oxygen atoms contained in the tertiary amine constitute a ring structure.

[4] The negative photosensitive material according to [3], wherein the ring is a morpholine ring.

[5] The negative photosensitive material according to any one of [1] to [4], wherein the tertiary amine is any of tertiary amines represented by the following formula (II).

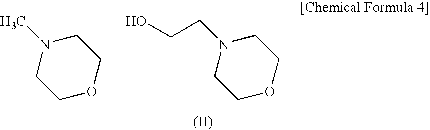

[6] The negative photosensitive material according to any one of [1] to [5], wherein the quaternary ammonium salt is represented by any of molecular structures of the following formula (III):

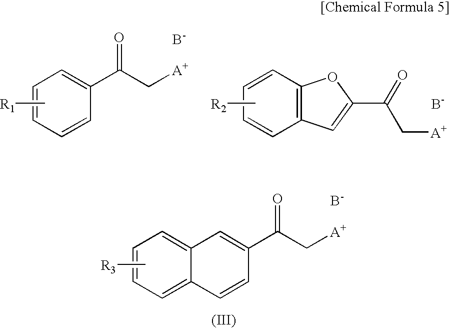

A⁺ represents a quaternary ammonium group; B⁻ represents a counterion; and R₁, R₂ and R₃ each represent a hydrogen atom or an organic group.

[7] The negative photosensitive material according to any one of [1] to [6], wherein, in the polyimide precursor represented by the general formula (I), X contains at least one selected from the following formula (IV) and Y contains at least one selected from the following formula (V).

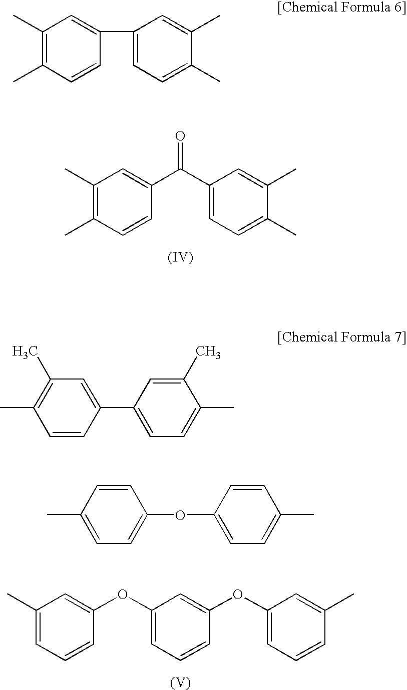

[8] The negative photosensitive material according to any one of [1] to [7], wherein, in the polyimide precursor represented by the general formula (I), X contains a structure represented by the following formula (VI) and Y contains a structure represented by the following formula (VII).

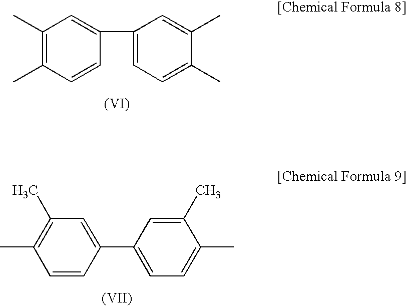

[9] The negative photosensitive material according to any one of [1] to [8], wherein the polyimide precursor is composed of acid dianhydride units and diamine units, and the number of moles of the acid dianhydride units is from 1.00 to 1.15 times, based on the number of moles of the diamine units.

[10] A laminate having a metal layer and a layer composed of the negative photosensitive material according to any one of [1] to [9] on the metal layer is provided.

[11] A circuit board having a patterned resin layer obtained through exposing to light for imidization and developing a layer composed of the negative photosensitive material according to any one of [1] to [9] is provided.

[12] The circuit board according to [11], wherein a thickness of the resin layer is from 5 to 20 μm is provided.

[13] The circuit board according to [11] or [12] used for a suspension head of a magnetic recording device is provided.

[14] An electronic device having the circuit board according to any one of [11] to [13] is provided.

### EFFECT OF THE INVENTION

According to the present invention, it is possible to provide a photosensitive polyimide material which has heat resistance equivalent to that of a non-photosensitive polyimide material useful as a conventionally known circuit material, does not greatly impair properties such as a linear thermal expansion coefficient or the like, and can be patterned with an aqueous developing solution such as an aqueous alkali solution or the like.

Furthermore, even when a thick film is produced with a polyimide precursor having a highly rigid molecular structure, the film can be patterned through the developing process.

### BEST MODE FOR CARRYING OUT THE INVENTION

Embodiments of the present invention will be described in more detail below.

1. Negative Photosensitive Material of the Present Invention

The present invention relates to a negative photosensitive material containing a quaternary ammonium salt in an amount of 5 to 30 weight parts, based on 100 weight parts of a polyimide precursor having repeating units of the following general formula (I). Furthermore, the quaternary ammonium salt is a photobase generator for generating a tertiary amine by irradiation with an active ray, and the tertiary amine contains one or more nitrogen atoms and oxygen atoms respectively in its molecule structure.

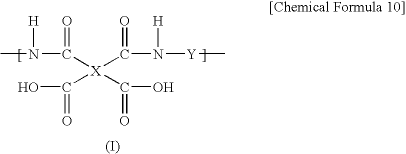

In the formula (I), X is a tetravalent aliphatic group or a tetravalent aromatic group; and Y is a divalent aliphatic group or a divalent aromatic group.

The linear thermal expansion coefficient of a metal foil such as copper, copper alloy, a stainless foil or the like is about 17 ppm/degrees centigrade. In particular, in order to make the linear thermal expansion coefficient of the polyimide small equivalent to that of the metal foil, it is preferable to select a polyimide precursor with a rigid molecular structure. However, since a polyimide resin only composed of a rigid molecular structure is generally hard and brittle, the resin is required to include a flexible molecular structure as well. Furthermore, transparency of the resin to exposure light wavelength and solubility of the resin in a developing solution also need to be considered.

In the polyimide precursor having repeating units of the following general formula (I), X of the repeating units is a tetravalent aliphatic group or a tetravalent aromatic group and preferably a tetravalent aromatic group, and is derived from tetracarboxylic dianhydride used as a raw material. On the other hand, Y is a divalent aliphatic group or a divalent aromatic group and preferably a divalent aromatic group, and is derived from diamine used as a raw material. When X is a tetravalent aromatic group, the —COOH group and the —CONH group of the formula (I) are preferably substituted at the ortho-position of the tetravalent aromatic group each other.

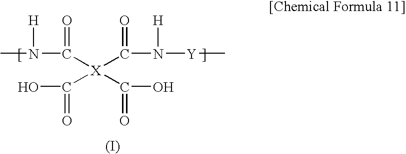

In the formula (I), X is a tetravalent aliphatic group or a tetravalent aromatic group; and Y is a divalent aliphatic group or a divalent aromatic group.

Examples of tetracarboxylic dianhydrides, raw materials of the polyimide precursor, include pyromellitic dianhydride, 4,4′-oxydiphthalic dianhydride, 3,3′,4,4′-benzophenonetetracarboxylic dianhydride, 3,3′,4,4′-diphenylsulfonetetracarboxylic dianhydride, 1,1,1,3,3,3-hexafluoropropane-2,2-diphthalic dianhydride, 3,3′,4,4′-biphenyltetracarboxylic dianhydride, 3,6-difluoro-1,2,4,5-benzenetetracarboxylic dianhydride, 3,3′,4,4′-diphenyl ether tetracarboxylic dianhydride, 1,4-dimethoxy-2,3,5,6-benzenetetracarboxylic dianhydride, 1,4-ditrimethylsilyl-2,3,5,6-benzenetetracarboxylic dianhydride, 1,4-bis(3,4-dicarboxylphenoxy)benzene dianhydride, 1,3-bis(3,4-dicarboxylphenoxy)benzene dianhydride, 3,3′,4,4′-diphenyl methanetetracarboxylic dianhydride, bis(3,4-dicarboxylphenoxy)dimethylsilane dianhydride, bis(3,4-dicarboxylphenoxy)methylalmine dianhydride, 4,4′-bis(3,4-dicarboxylphenoxy)biphenyl dianhydride, 4,4′-bis(3,4-dicarboxylphenoxy)diphenylsulfone dianhydride, 2,3,5,6-naphthalene tetracarboxylic dianhydride, 2,3,5,6-pyridine tetracarboxylic dianhydride, 2,3,6,7-quinoline tetracarboxylic dianhydride, 3,3′,4,4′-diphenylsulfide tetracarboxylic dianhydride, 3,3′,4,4′-diphenylsulfoxide tetracarboxylic dianhydride, 1,4-bis(3,4-dicarboxylphenylsulfonyl)benzene dianhydride, 1,4-bis(3,4-dicarboxylphenylthio)benzene dianhydride, 3,3″,4,4″-terphenyltetracarboxylic dianhydride, 4-phenylbenzophenone-3,3″,4,4″-tetracarboxylic dianhydride, 1,4-bis(3,4-dicarboxylbenzoyl)-benzene dianhydride, 4,4′-bis(3,4-dicarboxylphenoxy)benzophenone dianhydride, 4,4′-bis(3,4-dicarboxylphenoxy)diphenylsufoxide dianhydride, butane tetracarboxylic dianhydride, 1,2,3,4-cyclobutane tetracarboxylic dianhydride, 1,2-dimethyl-1,2,3,4-cyclobutane tetracarboxylic dianhydride, 1,3-dimethyl-1,2,3,4-cyclobutane tetracarboxylic dianhydride, 1,3-dichloro-1,2,3,4-cyclobutane tetracarboxylic dianhydride, 1,2,3,4-tetramethyl-1,2,3,4-cyclobutane tetracarboxylic dianhydride, 1,2,3,4-cyclopentane tetracarboxylic dianhydride, 1,2,4,5-cyclohexane tetracarboxylic dianhydride, 3,3′,4,4′-dicyclohexyl tetracarboxylic dianhydride, 2,3,5-tricarboxy cyclopentylacetic dianhydride, 3,5,6-tricarboxynorbornane-2-acetic dianhydride, 2,3,4,5-tetrahydrofuran tetracarboxylic dianhydride and the like.

Examples of diamines include para-phenylenediamine, 3,3′-dimethyl-4,4′-diaminobiphenyl, 2,2′-dimethyl-4,4′-diaminobiphenyl, 3,3′-dimethoxy-4,4′-diaminobiphenyl, 3,3′-dichloro-4,4′-diaminobiphenyl, 4,4′-diaminobenzophenone, m-bis(m-aminophenoxy)benzene, m-bis(p-aminophenoxy)benzene, p-bis(p-aminophenoxy)benzene, 4,4′-diaminodiphenylsulfone, 3,3′-diaminodiphenylsulfone, 4,4′-diaminodiphenylsulfoxide, bis[4-(4-aminophenoxy)phenyl]sulfone, bis[4-(3-aminophenoxy)phenyl]sulfone, 4,4′-bis(p-aminophenoxy)biphenyl, 4,4′-bis(m-aminophenoxy)biphenyl, bis[4-(4-aminophenoxy)phenyl]ether, 1,1,1,3,3,3-hexafluoro-2,2-bis(4-aminophenyl)propane, 1,1,1,3,3,3-hexafluoro-2,2-bis[4-(4-aminophenoxy)phenyl]propane, 1,1,1,3,3,3-hexafluoro-2,2-bis(3-amino-4-methylphenyl)propane, meta-phenylenediamine, 4,4′-diaminodiphenyl ether, 4,4′-diaminodiphenylsulfide, 3,4′-diaminodiphenyl ether, 1,4-bis(4-aminophenoxy)benzene, 1,3-bis(4-aminophenoxy)benzene, 1,1-meta-xylylenediamine, 1,3-propanediamine, tetramethylenediamine, pentamethylenediamine, hexamethylenediamine, heptamethylenediamine, octamethylenediamine, nonamethylenediamine, 4,4-diaminoheptamethylenediamine, 1,4-diaminocyclohexane, isophoronediamine, tetrahydrodicyclopentadienylenediamine, hexahydro-4,7-methanoindanylenedimethylenediamine, tricyclo[6.2.1.0^{2,7}]-undecyclenedimethyldiamine, 4,4′-methylene bis(cyclohexylamine), isophorone diamine and the like. A copolymer having a plurality of components may be used, or a blended polymer obtained by blending polymers having each component may be used.

Among the above materials, in view of obtaining polyimide having suitable rigidity and flexibility, a polyimide precursor prepared from a combination of a tetracarboxylic dianhydride selected from 3,3′,4,4′-biphenyltetracarboxylic dianhydride and 3,3′1,4,4′-benzophenonetetracarboxylic dianhydride, and a diamine selected from 3,3′-dimethyl-4,4′-diaminobiphenyl, 4,4′-diaminodiphenyl ether and 3,3′-(m-phenylenedioxy)dianiline is preferable. In particular, a combination of a tetracarboxylic dianhydride of 3,3′,4,4′-biphenyltetracarboxylic dianhydride, and a diamine including 3,3′-dimethyl-4,4′-diaminobiphenyl as a main component and 4,4′-diaminodiphenyl ether or 3,3′-(m-phenylenedioxy)dianiline as a sub-component, is more preferable. In such a case, the diamine composition ratio between the main component and the sub component is preferably from 70:30 to 95:5, and more preferably from 80:20 to 90:10. A combination of tetracarboxylic dianhydride of 3,3′,4,4′-biphenyltetracarboxylic dianhydride and diamine of 3,3′-dimethyl-4,4′-diaminobiphenyl, is further more preferable.

The polyimide precursor is composed of acid dianhydride units and diamine units, and the number of moles of acid dianhydride units is preferably from 1.00 to 1.15 times and more preferably from 1.05 to 1.10 times the number of moles of diamine units. In consideration of solubility of the polyimide precursor in an alkali developing solution, it is preferable to increase acid terminal groups of the polyimide precursor. That is, it is preferable that the number of moles of acid dianhydride units be greater than the number of moles of diamine units of the polyimide precursor. In this way the solubility of such polyimide precursor can be increased. Within this range, the polyimide precursor whose molecular weight is sufficient high can be prepared, and sufficient strength can be obtained in a film composed of a polyimide prepared from the polyimide precursor.

The solvent used for preparing a polyimide precursor through the dehydrating condensation reaction of the acid dianhydride with diamine is not particularly limited, and examples thereof include N-methyl-2-pyrrolidone (NMP), dimethylacetamide (DMAC), dimethylformamide (DMF) and the like. One or more kinds from these solvents can be suitably used.

In the present invention, the quaternary ammonium salt is not particularly limited, but it can be represented by the following structural formula and is a photobase generator for generating a tertiary amine by irradiation with an active ray. In the formula, Z is an aromatic group having a skeleton such as benzene, benzofuran, naphthalene, anthracene, phenanthrene, pyrene or the like.

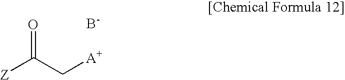

In the formula, A⁺ represents a quaternary ammonium group; B⁻ represents a counterion; and Z represents an aromatic group.

More preferably, the structure of the quaternary ammonium salt is represented by any of molecular structures of the following formula (III) having a skeleton such as benzene, benzofuran or naphthalene.

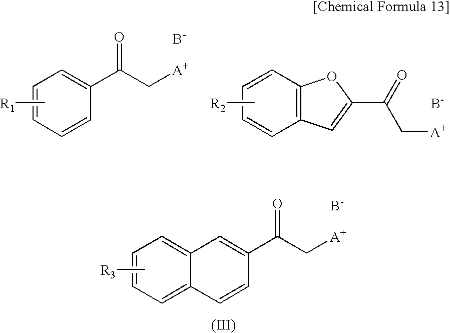

In the formula (III), A⁺ represents a quaternary ammonium group; B⁻ represents a counterion; and R₁, R₂ and R₃ each represent a hydrogen atom or an organic group.

Herein, R₁, R₂ and R₃ each represent a hydrogen atom or an organic group, and are not particularly limited, and specific examples of the organic group include a methyl group, an ethyl group, a propyl group, a butyl group, a pentyl group, a nitro group, a phenyl group, a phenoxy group, a phenylthio group, a phenylsulfonyl group, an amino group, a diethylamino group, a pyrrolidino group, a methoxy group, an imidazole group, a benzyloxy group and the like. One or two or more of R₁, R₂ and R₃ may each be contained. When two or more of R₁, R₂ and R₃ are contained, they may be the same or different.

A quaternary ammonium group A⁺ is irradiated with an active ray to generate a tertiary amine A containing one or more nitrogen atoms and oxygen atoms respectively in a molecule. Examples of such a tertiary amine include aliphatic amines and aromatic amines having an alkoxyl group, a carbonyl group, an ether bond and the like. Examples of the tertiary aliphatic amines include N-(2-hydroxyethyl)piperidine, dimethylethanolamine, N-formylmorpholine, 2-hydroxyethylmorpholine, N-methylmorpholine, 3-acetoxyquinuclidine, 3-hydroxyquinoclidine and the like.

Among the above tertiary aliphatic amines, amine compounds having nitrogen atoms and oxygen atoms constituting the same ring, specifically amine compounds having a morpholine ring are preferable. Preferable examples of the amine compounds having a morpholine ring are compounds represented by the following general formula (II).

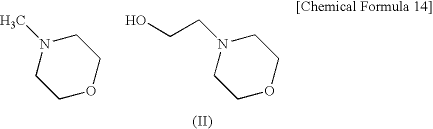

Examples of the tertiary aromatic amine include 2-(N-ethyl-m-toluidino)ethanol, N-ethyl-N-(2-hydroxyethyl)aniline, N-(m-tolyl)diethanolamine, N,N-diethanolaniline, 2,4,6-tris(dimethylaminomethyl)phenol, quinoxalidinone and the like.

A counterion B⁻ is not particularly limited, and examples thereof include amide anion, methide anion, borate anion, phosphate anion, sulfonate anion, carboxylate anion and the like. Preferable examples include hexafluorophosphate, tetraphenylborate, tetrabutylborate, tetrafluoroborate, tetraethylborate, butyltriphenylborate, dibutyldiphenylborate, tributylphenylborate, 4-methylbenzenesulfonate, 4-trifluoromethylbenzenesulfonate, trifluoromethanesulfonate, trifluorobutylsulfonate, benzenesulfonate, tosylate, tetra(perfluorophenyl)borate and the like.

Meanwhile, it is preferable that the quaternary ammonium salt have high capacity for absorbing exposure light to effectively generate a tertiary amine. Accordingly, in order to increase the capacity for absorbing light of the quaternary ammonium salt, an additive such as a photosensitizer and the like may be added to the material of the present invention. In addition, an additive such as a dissolution regulator, an adhesive aid or the like can also be added to the negative photosensitive material of the present invention. These additives can be used singly or in combination.

The quaternary ammonium salt needs to be contained in an amount of 5 to 30 weight parts and more preferably 10 to 20 weight parts, based on 100 weight parts of the polyimide precursor. Within this range, a development of the negative photosensitive material can be fully achieved without impairing the physical properties of the polyimide. Furthermore, the amount of an additive added is not particularly limited, and it is preferably from 0.1 to 10 weight parts, based on 100 weight parts of the polyimide precursor.

The negative photosensitive material of the present invention may be provided in the form of an amorphous liquid, or may be provided in the form of a film or as an applied film (coating film) formed on a surface of a board (for example, surface of a metal layer or the like) as well.

2. Action of Negative Photosensitive Material of the Present Invention

The negative photosensitive material of the present invention contains the quaternary ammonium salt for generating a tertiary amine by irradiation with an active ray along with the polyimide precursor. Accordingly, when the negative photosensitive material of the present invention is irradiated with an active ray, a tertiary amine is generated and imidization of the polyimide precursor is accelerated for curing.

Accordingly, when a part of a thin film made of the negative photosensitive material of the present invention is irradiated with an active ray, alkali development can be attained. This is because differences in solubility or dissolution rate with respect to the developing alkali solution can be obtained between exposed portions and unexposed portions.

Furthermore, one possible reason why the tertiary amine generated from the photobase generator according to the present invention has excellent effect in curing acceleration is that the one or more nitrogen atoms and oxygen atoms present in a molecule of the tertiary amine give high basicity to the tertiary amine. That is, the oxygen atom exhibiting electron donative property increases basicity of a non-covalent electron pair on the nitrogen atom of the tertiary amine, whereby curing accelerating effect of the tertiary amine can be improved. However, if the basicity of the tertiary amine is too high, an affinity for the polyimide precursor (solubility into the polyimide precursor solution) is decreased to reduce curing accelerating effect in some cases. Therefore, the basicity of the tertiary amine is preferably adjusted to fall within a proper range, for example, by introducing suitable a substituent group or an atom having different electron donating/withdrawing property to the tertiary amine. The tertiary amine generated from the photobase generator according to the present invention has the non-covalent electron pair on the nitrogen atom, the basicity of which is adjusted properly. Therefore, the tertiary amine has excellent effect in curing acceleration.

As a result, a thick film made of the polyimide precursor having a highly rigid molecular structure can be cured through accelerating imidization of the polyimide precursor in the portions exposed to light.

The polyimide having a highly rigid molecular structure has a low linear thermal expansion coefficient. Therefore, the negative photosensitive material of the present invention is suitable for polyimide to be an insulation layer or a protection layer of a suspension board, which layers are required to be thick films with a low thermal expansion coefficient.

The light absorption peak of the polyimide having a highly rigid molecular structure shifts to longer wavelengths. And more, light having long wavelength hardly passes through the polyimide film in the thickness direction. These are also suggested from the following Reference Examples.

A polyamic acid solution obtained by dissolving BPDA (3,3′,4,4′-biphenyltetracarboxylic dianhydride)/o-DDBP (3,3′-dimethyl-4,4′-diaminobiphenyl) in a solvent and a polyamic acid solution obtained by dissolving ODPA (3,3′,4,4′-diphenyl ether tetracarboxylic dianhydride)/o-DDBP in a solvent were respectively prepared.

Each of the above polyamic acid solution was applied on a prescribed board to be a film. The applied film was dried, heated, and then imidized. Its linear thermal expansion coefficient and transmittance of light at a wavelength of 365 nm were measured.

The linear thermal expansion coefficient of the polyimide was measured according to the TMA method (Thermal Mechanical Analysis method). Firstly, a sample of 4 mm in width and 20 mm was prepared. Secondly, an amount of change in the length in the tension direction of the sample from 100 to 200 degrees centigrade at a temperature elevation rate of 10 degrees centigrade/min while applying a load of 5 g was measured. Finally, the linear thermal expansion coefficient was calculated from an average amount at 100 to 200 degrees centigrade. Light transmittance was measured by UV-VIS spectrophotometer. The results are shown in Table 1.

TABLE 1

| Kind of polyimide | Linear thermal expansion | Transmittance |
|---|---|---|
| resin | coefficient (ppm/° C.) | (%) |
| BPDA/o-DDBP | 10 | 0 |
| ODPA/o-DDBP | 20 | 27 |

As clear from Table 1, it is found that a linear thermal expansion coefficient of polyimide containing BPDA as acid dianhydride units having a molecular structure with high rigidity is lower than that of polyimide containing ODPA as acid dianhydride units having a molecular structure with low rigidity. On the other hand, it is found that a light transmittance of the polyimide containing BPDA is lower than that of the polyimide containing ODPA. As above, the polyimide having a highly rigid molecular structure has low linear thermal expansion coefficient but low light transmittance so that it is suggested that imidization through a photo-curing of the precursor (polyamic acid) be hardly attained.

Meanwhile, the light absorption peak the polyimide having a highly rigid molecular structure shifted to longer wavelengths, which is also suggested from the following Reference Examples.

A polyamic acid solution was prepared by adding a BPDA/o-DDBP precursor solution to an ODPA/CHA (cyclohexylamine) precursor solution, wherein the additive amount of the BPDA/o-DDBP precursor is adjusted. Polyimide films were formed from each of polyamic acid solutions, and light transmittances through the films at wavelengths of 365 nm and 405 nm were measured. The results are shown in Table 2.

TABLE 2

| ODPA/CHA: | | |
|---|---|---|
| BPDA/o-DDBP | 365 nm | 405 nm |
| (weight ratio) | Transmittance (%) | Transmittance (%) |
| 1:0 | 98 | 99 |
| 3:1 | 26 | 94 |
| 1:1 | 6 | 87 |
| 1:3 | 1 | 79 |
| 0:1 | 0 | 71 |

As clear from Table 2, it is found that light transmittance at each of the wavelengths is decreasing as the additive amount of BPDA/o-DDBP to the ODPA/CHA polyimide resin increase, whereas light transmittance at a wavelength of 405 nm is higher than light transmittance at a wavelength of 365 nm.

In this manner, it is found that, since the light absorption peak of the polyimide having a highly rigid molecular structure shifted to longer wavelengths, light hardly passes through the thick film made of the polyimide. Even in this case, the photobase generator of the present invention is particularly useful.

3. Use of Negative Photosensitive Material of the Present Invention

As described below, a laminate having a metal foil and a patterned polyimide film formed thereon is prepared, which patterned polyimide film is formed through exposing to light and developing the negative photosensitive material of the present invention.

The negative photosensitive material solution containing a polyimide precursor and a quaternary ammonium salt, i.e., a photobase generator is applied on the metal foil, and is dried (pre-dried) to form a film to be patterned. The pre-dried film thickness is preferably thicker (for example, from about 20 to 50 μm) than predefined thickness in consideration of dissolution of the film into the developing solution in development.

Pre-drying is carried out by heating until tackiness is eliminated. However, by heating at a very high temperature, imidization of the polyimide precursor proceeds and solubility in the developing solution is decreased excessively so that the development hardly occurs, that is, the patterning of the film cannot be potentially achieved. Accordingly, the drying temperature is preferably from about 80 to 100 degrees centigrade. Furthermore, the drying time is preferably from about 5 to 20 minutes, but not particularly limited to this.

The patterning of the negative photosensitive material is preferably achieved through irradiating the film with an active ray via a mask, or scanning exposure of the film. Namely, the negative photosensitive material is exposed to light for patterning, and then heated (post-curing), whereby a negative latent image is formed. At the post-curing step, the film is preferably heated at a high temperature for accelerating imidization of the exposed portion. However, the heating at a very high temperature advance imidization in the unexposed part so that consequently a negative image cannot be formed without obtaining the contrast of solubility in the developing solution between the exposed part and the unexposed part. Accordingly, post-curing is carried out preferably at a temperature in the range of 140 to 200 degrees centigrade and more preferably in the range of 150 to 170 degrees centigrade.

As used herein, “active ray” refers to visible light, ultraviolet ray, electron beam, X-ray and the like. Its light source is not particularly limited, and examples thereof include high pressure mercury lamps, ultrahigh pressure mercury lamps, low pressure mercury lamps, metal halide lamps, xenon lamps, fluorescent lamps, tungsten lamps, argon lasers, helium cadmium lasers and the like. Furthermore, irradiation energy is preferably from 100 to 5,000 mJ/cm².

Thereafter, the unexposed portions of the film are removed with an aqueous developing solution such as an aqueous alkali solution or the like through the development treatment, whereby a negative image can be formed.

Examples of the aqueous developing solution for developing the negative photosensitive material of the present invention include an aqueous solution of tetramethyl ammonium hydroxide, an aqueous solution of sodium carbonate and the like. The alkali concentration is preferably in the range of 2 to 10 weight %. As necessary, a lower aliphatic alcohol such as methanol, ethanol, n-propanol, isopropanol and the like may be added to the above aqueous alkali solution. The amount of alcohol added is usually not more than 50 weight %. Furthermore, it is suitable that the developing temperature is usually in the range of 25 to 50 degrees centigrade.

The formed negative image is heated at a high temperature to imidize the residual polyimide precursor, whereby it is possible to obtain a patterned polyimide film. The imidization is carried out through the heating in vacuum or in an inert gas atmosphere at about 300 to 400 degrees centigrade for several hours.

The laminate thus obtained by forming polyimide on a metal foil can be used, for example, as a circuit board to be mounted on various electronic devices, communication devices and transportation equipment.

Examples of the circuit board include flexible laminates, multilayer printed circuit boards and the like. Among them, preferably used is a suspension head requiring position accuracy for adhering to other member such as a suspension board (in particular, “flexure”) of a magnetic recording device, and requiring stability in use environment.

The metal foil constituting the circuit board of the present invention is not particularly limited as long as it is a metal foil usually used for a circuit board, and preferable examples include copper, copper alloy, stainless and the like. When a circuit board is formed, in order to prevent warpage of the board, polyimide and/or the metal foil are preferably selected such that the difference in linear thermal expansion coefficient between the metal foil to be a board and the imidized polyimide can be made as small as possible. Specifically, the difference in linear thermal expansion coefficient between the metal foil and the polyimide is preferably in the range of +10 ppm/degrees centigrade and more preferably +5 ppm/degrees centigrade.

When the negative photosensitive material of the present invention is applied to the protection layer of the suspension board, a laminate obtained by laminating a metal board of a stainless foil or the like, an insulation layer, and a conductor layer in this order are provided, and then the negative photosensitive material of the present invention to be a protection layer is formed on the conductor layer.

Before the negative photosensitive material of the present invention is given, the conductor layer may be patterned by plating, fine processing technology or the like, or may not be patterned.

When the conductor layer is not patterned before the negative photosensitive material of the present invention is given, the negative photosensitive material may be provided on the copper layer, and then patterned by exposure to light and development, and further, the conductor layer is patterned by etching of the exposed part with an etchant. Examples of the etching method include dry etching, wet etching, electrolytic etching and the like.

Examples of the material of the conductor layer include copper, nickel, gold or their alloy and the like, and preferably is copper or its alloy from the viewpoint of high conductivity.

The thickness of the polyimide to be a protection layer or an insulation layer on a suspension board is preferably from 5 to 20 μm and more preferably about 10 μm.

In addition, depending on the use, a layer composed of the negative photosensitive material of the present invention may be formed on a semiconductor wafer instead of the metal foil.

### EXAMPLES

1. Effect of Kind of Photobase Generator on Developing Property

The present invention is illustrated in detail below with reference to Examples. Compounds and their abbreviations used in Example are described below.

BPDA: 3,3′,4,4′-biphenyltetracarboxylic dianhydride

BTDA: 3,3′,4,4′-benzophenonetetracarboxylic dianhydride

o-DDBP: 3,3′-dimethyl-4,4′-diaminobiphenyl

ODA: 4,4′-diaminodiphenyl ether

APB: 3,3′-(m-phenylenedioxy)dianiline

DMAc: dimethyl acetamide

TMAH: aqueous solution of tetramethyl ammonium hydroxide

Photobase Generator (A):

### N-(2-acetylnaphthone)-N,N,N-tributylammonium tetraphenylborate

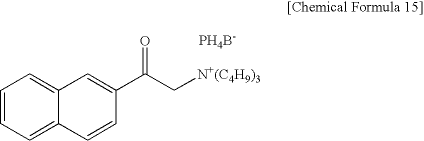

Photobase Generator (B):

### N-(2-acetylnaphthone)-N-methylpiperidinium tetraphenylborate

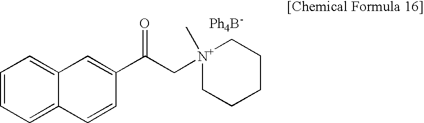

Photobase Generator (C):

### N-(2-acetylnaphthone)-N-methylmorpholinium tetraphenylborate

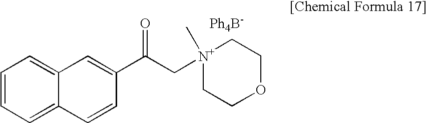

Synthesis of Photobase Generator (A)

2-bromoacetylnaphthalene was dissolved in acetonitrile and tributylamine was slowly added dropwise in not less than an equimolar amount, based on 2-bromoacetylnaphthalene, and the resulting mixture was stirred at 70 degrees centigrade for 3 hours. Thereafter, acetonitrile was removed through concentrating, ethyl acetate was added, and the precipitated white crystal was filtered out. Next, the resulting white crystal was completely dissolved in water at 50 degrees centigrade, and an equimolar amount of an aqueous sodium tetraphenylborate solution was slowly added dropwise and thoroughly stirred. The precipitated white crystal was filtered out and fully dried to obtain a photobase generator (A) (N-(2-acetylnaphthone)-N,N,N-tributylammonium tetraphenylborate).

Synthesis of Photobase Generator (B)

2-bromoacetylnaphthalene was dissolved in ethyl acetate and 1-methyl-piperidine was slowly added dropwise in not less than an equimolar amount based on 2-bromoacetylnaphthalene, and the resulting mixture was stirred at 40 degrees centigrade for 2 hours. Thereafter, the solution was cooled down to room temperature and the precipitated white crystal was filtered out. Next, the resulting white crystal was completely dissolved in water, and an equimolar amount of an aqueous sodium tetraphenylborate solution was slowly added dropwise and thoroughly stirred. The precipitated white crystal was filtered out and fully dried to obtain a photobase generator (B) (N-(2-acetylnaphthone)-N-methylpiperidinium tetraphenylborate).

Synthesis of Photobase Generator (C)

In the same manner as in the photobase generator (B), 2-bromoacetylnaphthalene was dissolved in ethyl acetate, and 4-methylmorpholine was slowly added dropwise in not less than an equimolar amount based on 2-bromoacetylnaphthalene, and then the resulting mixture was stirred at 40 degrees centigrade for 7 hours. Thereafter, the solution was cooled down to room temperature and the precipitated white crystal was filtered out. Next, the resulting white crystal was completely dissolved in a 1:1 mixture of water and methanol, and an equimolar amount of an aqueous sodium tetraphenylborate solution was slowly added dropwise and thoroughly stirred. The precipitated white crystal was filtered out and fully dried to obtain a photobase generator (C) (N-(2-acetylnaphthone)-N-methylmorpholinium tetraphenylborate).

### Example 1

5.88 g (0.0200 mol) of BPDA as acid dianhydride, 3.43 g (0.0162 mol) of o-DDBP and 0.84 g (0.0029 mol) of APB as diamine were dissolved in 53.29 g of DMAc. The molar ratio of the acid dianhydride to the diamines was 1.05. This solution was stirred for 12 hours, whereby a polyamic acid solution, i.e., a polyimide precursor, was obtained. The photobase generator (C) was added such that it was 10 weight % based on the polyamic acid in the above polyamic acid solution to prepare a negative photosensitive material solution.

Next, the above solution was added dropwise onto the stainless foil having a thickness of 18 μm for forming a film by a spin coating method, and the resulting material was pre-dried in a nitrogen atmosphere at 80 degrees centigrade for 5 minutes. The thickness of the pre-dried negative photosensitive material film was 17 μm. Thereafter, the above pre-dried negative photosensitive material film was irradiated with an active ray of 2,000 mJ/cm² by using an ultrahigh pressure mercury lamp via a photomask. Furthermore, the resulting film was heated in a nitrogen atmosphere at 160 degrees centigrade for 5 to 7 minutes for carrying out post-curing, and then TMAH 5 weight % aqueous solution (0.5 mol)/ethanol (0.5 mol) solution were used as a developing solution for carrying out development at 40 degrees centigrade to form a negative image. Formation of the negative image was determined by observing visually or using a microscope whether patterns were formed or not after development. Wherein “not forming patterns” means that a whole of the film is dissolved or no part of the film is dissolved during development.

Then, a residual percentage of the film in the exposed part when the negative image was formed was measured. And a developing time required for forming the negative image (pattern) from the beginning of development was measured. Three kinds of samples were prepared with the post-curing time of 5, 6 and 7 minutes respectively. The residual percentage of the film was obtained from the following formula,

The residual percentage of the film (%)=film thickness after development/film thickness before development×100

The results are shown in Table 3.

### Comparative Example 1

A negative photosensitive material was prepared in the same manner as in Example 1, except that the photobase generator (A) was used instead of the photobase generator (C) in Example 1 to form a film on a stainless foil. Thereafter, exposure to light, post-curing and development were carried out in the same manner as in Example 1 to form a negative image. Then, the residual percentage of the exposed part of the film when the negative image was formed and the developing time were measured. The results are shown in Table 3.

### Comparative Example 2

A negative photosensitive material was prepared in the same manner as in Example 1, except that the photobase generator (B) was used instead of the photobase generator (C) in Example 1 to form a film on a stainless foil. Thereafter, exposure to light, post-curing and development were carried out in the same manner as in Example 1 to form a negative image. Then, the percentage residual film of the exposed portion when the negative image was formed and the developing time were measured. The results are shown in Table 3.

### Comparative Example 3

A negative photosensitive material was prepared in the same manner as in Example 1, except that 1-(2-oxo-2-phenylethyl)-4-aza-1-azonibicyclo(2.2.2)octane bromide was used instead of the photobase generator (C) in Example 1, and 2-isopropylthioxanthone was added as a sensitizer in an amount of 10 weight 0 based on the polyamic acid to the above polyamic acid solution to form a film on a stainless foil. Thereafter, exposure to light, post-curing and development were carried out in the same manner as in Example 1 to form a negative image. Then, the residual percentage of the exposed part of the film when the negative image was formed and the developing time were measured. The results are shown in Table 3.

### Comparative Example 4

A negative photosensitive material was prepared in the same manner as in Example 1, except that 1-(2-(4-methylphenyl)-2-oxoethyl)-4-aza-1-azonibicyclo(2.2.2)octane bromide was used instead of the photobase generator (C) in Example 1, and 2-isopropylthioxanthone was added as a sensitizer in an amount of 10 weight % based on the polyamic acid to the above polyamic acid solution to form a film on a stainless foil. Thereafter, exposure to light, post-curing and development were carried out in the same manner as in Example 1 to form a negative image. Then, the residual percentage of the exposed part of the film when the negative image was formed and the developing time were measured. The results are shown in Table 3.

TABLE 3

| | | Post-curing time (minutes) | | |
|---|---|---|---|---|
| | | 5 | 6 | 7 |
| Example 1 | Residual | 0.0 | 23.8 | 29.7 |
| | Percentage (%) | | | |
| | Developing | 30 | 60 | 120 |
| | time (seconds) | | | |
| Comparative | Residual | 0.0 | 7.4 | 9.4 |
| Example 1 | Percentage (%) | | | |
| | Developing | 30 | 120 | 160 |
| | time (seconds) | | | |
| Comparative | Residual | 0.0 | 12.1 | 19.7 |
| Example 2 | Percentage (%) | | | |
| | Developing | 40 | 60 | 100 |
| | time (seconds) | | | |
| Comparative | Residual | 0.0 | 0.0 | 0.0 |
| Example 3 | Percentage (%) | | | |
| | Developing | 30 | 50 | 90 |
| | time (seconds) | | | |
| Comparative | Residual | 0.0 | 0.0 | 0.0 |
| Example 4 | Percentage (%) | | | |
| | Developing | Note) | Note) | Note) |
| | time (seconds) | | | |

Note:
all dissolved in a developing solution at once

As shown in Table 3, it was found that, in the case of post-curing for the same period of time, the developing time of the negative photosensitive material film of Example 1 using the photobase generator (C) was substantially shorter than those of the negative photosensitive material films of Comparative Examples 1 and 2 using the other photobase generator, and the residual percentage of the film was remarkably high. Accordingly, it was found that the photosensitivity of the photobase generator (C) was high. On the other hand, the negative photosensitive material film of Comparative Example 3 was finally all dissolved in the developing solution without forming any patterns, while the negative photosensitive material film of Comparative Example 4 was all dissolved in the developing solution at once. From both of the films, negative image could not be obtained.

2. Measurement of Linear Thermal Expansion Coefficient of Polyimide Obtained Through Imidizing Negative Photosensitive Material Film Containing Photobase Generator (C) with Exposure to Light and Development.

### Example 2

5.88 g (0.0200 mol) of BPDA as acid dianhydride and 3.87 g (0.0182 mol) of o-DDBP as diamine were dissolved in 39.01 g of DMAc. The molar ratio of the acid dianhydride to the diamine was 1.096. This solution was stirred for 12 hours, whereby a polyamic acid solution was obtained. The photobase generator (C) was added to the above polyamic acid solution to an amount of 30 weight % based on the polyamic acid to prepare a negative photosensitive material solution.

Next, the above solution was added dropwise onto the stainless foil having a thickness of 20 μm, and is formed into a film with a spin coating method in the same manner as in Example 1, and the resulting material was pre-dried in a nitrogen atmosphere at 100 degrees centigrade for 5 minutes. Thereafter, the above pre-dried negative photosensitive material film was irradiated via a photomask with an active ray of 1,000 mJ/cm² with an ultrahigh pressure mercury lamp. Furthermore, the resulting film was heated in a nitrogen atmosphere at 170 degrees centigrade for 7 minutes for carrying out post-curing, and then a TMAH aqueous solution (5 weight %) was used as a developing solution for carrying out development at 40 degrees centigrade to form a negative image. Finally, the resulting film was heated in a nitrogen atmosphere at 350 degrees centigrade for 1 hour for carrying out imidization to form a patterned polyimide layer. The thickness of this polyimide was 7 μm. Furthermore, the linear thermal expansion coefficient of this polyimide was 12 ppm/degrees centigrade.

The linear thermal expansion coefficient of the stainless foil used as a board was 17 ppm/degrees centigrade. The linear thermal expansion coefficient was measured according to the TMA method (Thermal Mechanical Analysis method). Firstly, a sample of 4 mm in width and 20 mm was prepared. Secondly, an amount of change in the length in the tension direction of the sample from 100 to 200 degrees centigrade at a temperature elevation rate of 10 degrees centigrade/min while applying a load of 5 g was measured. Finally, the linear thermal expansion coefficient was calculated from an average amount at 100 to 200 degrees centigrade.

### Example 3

5.88 g (0.0200 mol) of BPDA, 2.14 g (0.0066 mol) of BTDA as acid dianhydride, 4.58 g (0.0216 mol) of o-DDBP and 0.7622 g (0.0038 mol) of ODA as diamine were dissolved in 53.48 g of DMAc. The molar ratio of acid dianhydride to diamine was 1.050. This solution was stirred for 12 hours, whereby a polyamic acid solution, i.e., a polyimide precursor, was obtained. The photobase generator (C) was added to the above polyamic acid solution such that it was 30 weight % based on the polyamic acid to prepare a negative photosensitive material solution.

Next, the above solution was added dropwise onto the stainless foil having a thickness of 20 μm, and was formed into a film by spin coating in the same manner as in Example 2, and the resulting material was pre-dried in a nitrogen atmosphere at 100 degrees centigrade for 5 minutes. Thereafter, the pre-dried negative photosensitive material film was irradiated via a photomask with an active ray 2,500 mJ/cm² by using an ultrahigh pressure mercury lamp. Furthermore, the resulting film was heated in a nitrogen atmosphere at 160 degrees centigrade for 8 minutes for carrying out post-curing, and then a TMAH aqueous solution (5 weight %) was used as a developing solution for carrying out development at 40 degrees centigrade to form a negative image. Finally, the resulting film was heated in a nitrogen atmosphere at 350 degrees centigrade for 1 hour in the same manner as in Example 2 for carrying out imidization to form a patterned polyimide layer. The thickness of this polyimide was 6 μm. Furthermore, the linear thermal expansion coefficient of this polyimide was 22 ppm/degrees centigrade.

### Example 4

A negative image was formed in the same manner as in Example 3, except that the additive amount of the photobase generator (C) in Example 3 was changed to 5 weight %. The linear thermal expansion coefficient of the imidized polyimide was 22 ppm/degrees centigrade.

### Example 5

5.88 g (0.0200 mol) of BPDA as acid dianhydride, 3.25 g (0.0153 mol) of o-DDBP and 0.54 g (0.0027 mol) of ODA as diamine were dissolved in 38.68 g of DMAc. The molar ratio of acid dianhydride to diamine was 1.100. This solution was stirred for 12 hours, whereby a polyamic acid solution, i.e., a polyimide precursor, was obtained. The photobase generator (C) was added to the above polyamic acid solution to an amount of 10 weight % based on the polyamic acid to prepare a negative photosensitive material solution.

Next, the above solution was added dropwise onto the stainless foil having a thickness of 20 μm, and was formed into a film by a spin coating method in the same manner as in Example 2, and the resulting material was pre-dried in a nitrogen atmosphere at 100 degrees centigrade for 5 minutes. Thereafter, the pre-dried negative photosensitive material film was irradiated via a photomask with an active ray of 500 mJ/cm² by using an ultrahigh pressure mercury lamp. Furthermore, the resulting film was heated in a nitrogen atmosphere at 160 degrees centigrade for 7 minutes for carrying out post-curing, and then a TMAH aqueous solution (5 weight %) was used as a developing solution for carrying out development at 40 degrees centigrade to form a negative image. Finally, the resulting film was heated in a nitrogen atmosphere at 350 degrees centigrade for 1 hour in the same manner as in Example 2 for carrying out imidization to form a patterned polyimide layer. The thickness of this polyimide was 7 μm. Furthermore, the linear thermal expansion coefficient of this polyimide was 19 ppm/degrees centigrade.

### Example 6

5.88 g (0.0200 mol) of BPDA as acid dianhydride, 3.44 g (0.0162 mol) of o-DDBP and 0.57 g (0.0028 mol) of ODA as diamine were dissolved in 56.03 g of DMAc. The molar ratio of the acid dianhydride to the diamine was 1.049. This solution was stirred for 12 hours, whereby a polyamic acid solution, i.e., a polyimide precursor, was obtained. The photobase generator (C) was added to the above polyamic acid solution to an amount of 10 weight % based on the polyamic acid to prepare a negative photosensitive material solution.

Next, the above solution was added dropwise onto the stainless foil having a thickness of 20 μm, was formed into a film by a spin coating method in the same manner as in Example 2, and the resulting material was pre-dried in a nitrogen atmosphere at 80 degrees centigrade for 5 minutes. Thereafter, the pre-dried negative photosensitive material film was irradiated via a photomask with an active ray of 500 mJ/cm² by using an ultrahigh pressure mercury lamp. Furthermore, the resulting film was heated in a nitrogen atmosphere at 160 degrees centigrade for 8 minutes for carrying out post-curing, and then a TMAH aqueous solution (5 weight %) was used as a developing solution for carrying out development at 40 degrees centigrade to form a negative image. Finally, the resulting film was heated in a nitrogen atmosphere at 350 degrees centigrade for 1 hour in the same manner as in Example 2 for carrying out imidization to form a patterned polyimide layer. The thickness of this polyimide was 6 μm. The linear thermal expansion coefficient of this polyimide was 15 ppm/degrees centigrade.

### Example 7

5.88 g (0.0200 mol) of BPDA as acid dianhydride, 3.43 g (0.0162 mol) of o-DDBP and 0.84 g (0.0029 mol) of APB as diamine were dissolved in 53.29 g of DMAc. The molar ratio of the acid dianhydride to the diamine was 1.050. This solution was stirred for 12 hours, whereby a polyamic acid solution, i.e., a polyimide precursor, was obtained. The photobase generator (C) was added to the above polyamic acid solution to an amount of 10 weight % based on the polyamic acid to prepare a negative photosensitive material solution.

Next, the above solution was added dropwise onto the stainless foil having a thickness of 20 μm, and is formed into a film by a spin coating method in the same manner as in Example 2, and the resulting material was pre-dried in a nitrogen atmosphere at 80 degrees centigrade for 5 minutes. Thereafter, the pre-dried negative photosensitive material film was irradiated via a photomask with an active ray of 5,000 mJ/cm² by using an ultrahigh pressure mercury lamp. Furthermore, the resulting film was heated in a nitrogen atmosphere at 160 degrees centigrade for 6 minutes for carrying out post-curing, and then a TMAH aqueous solution (5 weight %) was used as a developing solution for carrying out development at 40 degrees centigrade to form a negative image. Finally, the resulting film was heated in a nitrogen atmosphere at 350 degrees centigrade for 1 hour in the same manner as in Example 2 for carrying out imidization to form a patterned polyimide layer. The thickness of this polyimide was 7 μm. The linear thermal expansion coefficient of this polyimide was 17 ppm/degrees centigrade.

### Comparative Example 5

A negative photosensitive material was prepared in the same manner as in Example 2, except that the added amount of the photobase generator (C) in Example 5 was changed to 3 weight % to form a film on a stainless foil. Thereafter, exposure to light, post-curing and development were carried out, but conditions under which the forming a negative image can be achieved were not found.

### Comparative Example 6

A negative photosensitive material was prepared in the same manner as in Example 2, except that 2-methyl-1-[4-(methylthio)phenyl]-2-morpholinopropane-1 represented by the following general formula (VIII), known to be a base generator by an active ray, was used instead of the photobase generator (C) in Example 2 to form a film on a stainless foil. Thereafter, exposure to light, post-curing and development were carried out, but conditions under which the forming a negative image can be achieved were not found.

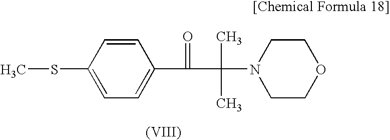

### INDUSTRIAL APPLICABILITY

According to the present invention, it is possible to provide a photosensitive polyimide material which has heat resistance equivalent to that of the polyimide material, which is conventionally known as a non-photosensitive material useful for a circuit, does not greatly impair characteristics such as a linear thermal expansion coefficient and the like. The photosensitive polyimide material can be patterned with an aqueous developing solution such as an aqueous alkali solution or the like. And a circuit board using the photosensitive polyimide material is also provided. In particular, it is useful as the polyimide for insulation layer or protective layer of a suspension board of a magnetic recording device.

What is claimed is:

1. A negative photosensitive material containing a quaternary ammonium salt in an amount of 5 to 30 weight parts based on 100 weight parts of a polyimide precursor having repeating units of the following general formula (I), wherein:
said quaternary ammonium salt is a photobase generator for generating a tertiary amine by irradiation with an active ray, and
said tertiary amine contains one or more nitrogen atoms and oxygen atoms respectively in a molecule, 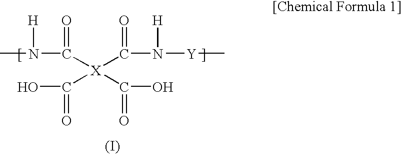
wherein, in the formula (I),
X is a tetravalent aliphatic group or a tetravalent aromatic group, and
Y is a divalent aliphatic group or a divalent aromatic group.

2. The negative photosensitive material according to claim 1, wherein said tertiary amine is a tertiary aliphatic amine.

3. The negative photosensitive material according to claim 1, wherein said nitrogen atom and said oxygen atom contained in said tertiary amine constitute a ring structure.

4. The negative photosensitive material according to claim 3, wherein said ring is a morpholine ring.

5. The negative photosensitive material according to claim 4, wherein said tertiary amine is any of tertiary amines represented by the following formula (II).

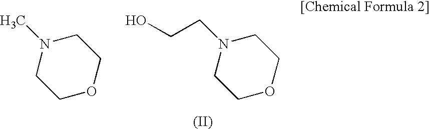

6. The negative photosensitive material according to claim 1, wherein said quaternary ammonium salt is represented by any of molecular structures of the following formula (III), 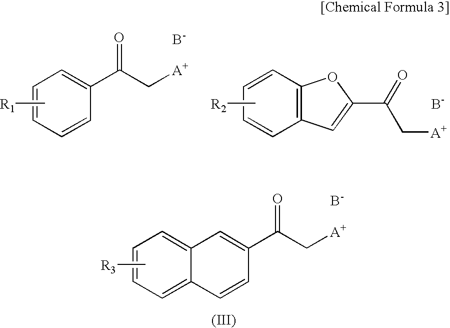
wherein
A⁺ represents a quaternary ammonium group,
B⁻ represents a counterion, and
R₁, R₂ and R₃ each represents a hydrogen atom or an organic group.

7. The negative photosensitive material according to claim 1, wherein, in said polyimide precursor represented by the general formula (I),
X contains at least one selected from the following formula (IV), and
Y contains at least one selected from the following formula (V).

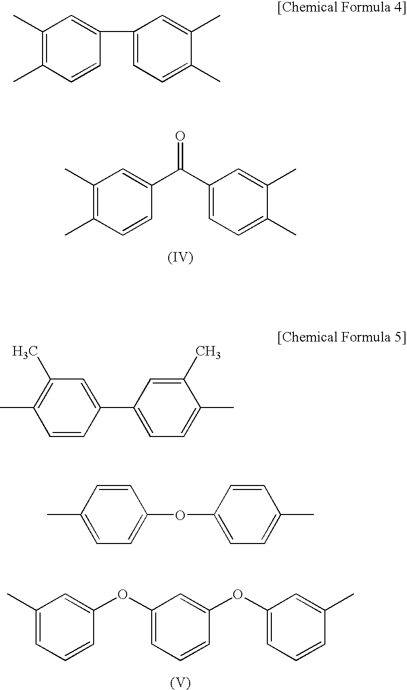

8. The negative photosensitive material according to claim 1, wherein, in said polyimide precursor represented by the general formula (I),
X contains a structure represented by the following formula (VI), and
Y contains a structure represented by the following formula (VII).

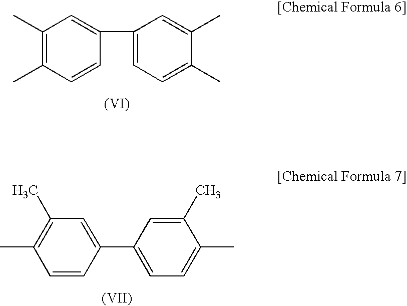

9. The negative photosensitive material according to claim 1, wherein:
said polyimide precursor comprises acid dianhydride units and diamine units, and
the number of moles of the acid dianhydride units is from 1.00 to 1.15 times the number of moles of the diamine units.

10. A laminate having a metal layer and a layer composed of the negative photosensitive material according to claim 1 on the metal layer.

11. A circuit board having a patterned resin layer obtained through exposing to light for imidization and developing a layer composed of the negative photosensitive material according to claim 1.

12. A circuit board having a patterned resin layer obtained through exposing to light for imidization and developing a layer composed of the negative photosensitive material according to claim 7.

13. The circuit board according to claim 11, wherein a thickness of said resin layer is from 5 to 20 μm.

14. The circuit board according to claim 12, wherein a thickness of said resin layer is from 5 to 20 μm.

15. The circuit board according to claim 11 used for a suspension head of a magnetic recording device.

16. An electronic device having the circuit board according to claim 11.
